(19) United States
(12) Patent Application Publication
(10) Pub. No.: US 2024/0038809 A1
(43) Pub. Date: Feb. 1, 2024

(54) IMAGE SENSORS

(71) Applicant: Samsung Electronics Co., Ltd., Suwon-si (KR)

(72) Inventors: Ja Meyung Kim, Suwon-si (KR); Sung In Kim, Suwon-si (KR); Yeon Soo Ahn, Suwon-si (KR)

(21) Appl. No.: 18/333,191

(22) Filed: Jun. 12, 2023

(30) Foreign Application Priority Data
Jul. 26, 2022 (KR) 10-2022-0092391

(51) Int. Cl. H01L 27/146

(52) U.S. Cl. CPC H01L 27/1463; H01L 27/14603; H01L 27/14636; H01L 27/14621

(57) ABSTRACT

An image sensor includes a substrate including a first face and a second face, the second face being opposite the first face in a first direction; a photoelectric conversion area disposed in the substrate; an active area disposed in the substrate and on the photoelectric conversion area; an element isolation pattern extending from the first face of the substrate into the substrate and defining the active area; and a transfer gate electrode including: a first portion extending from the first face of the substrate and extending through the element isolation pattern; and a second portion disposed on the active area, wherein the first portion extends through a bottom face of the element isolation pattern, wherein a vertical level of a bottom face of the first portion is lower than a vertical level of the bottom face of the element isolation pattern.

### CROSS-REFERENCE TO RELATED APPLICATION

This application claims priority from Korean Patent Application No. 10-2022-0092391 filed on Jul. 26, 2022, in the Korean Intellectual Property Office, and all the benefits accruing therefrom under 35 U.S.C. 119, the contents of which in its entirety are herein incorporated by reference.

### BACKGROUND

The present disclosure relates to image sensors.

Image sensors include semiconductor devices that convert optical information into electrical signals. Image sensors include a CCD (charge-coupled device) based image sensor and a CMOS (complementary metal-oxide semiconductor) based image sensor.

The image sensor may be embodied in a form of a package. In this case, the package may be configured to have a structure that protects the image sensor and, at the same time, allows light to be incident on a photo receiving surface or a sensing area of the image sensor.

### SUMMARY

Some implementations of the present disclosure provide an image sensor compatible with improved design freedom. In some implementations, a trench in which an electrode is formed may be formed through an element isolation pattern, e.g., by etching through the element isolation pattern, instead of only etching through an active area of a substrate to form the trench. In some implementations, an electrode can pass through/by the element isolation pattern, e.g., to have a bottom surface below a bottom surface of the element isolation pattern and/or in a trench that is adjacent to (e.g., directly in contact with) a sidewall of the element isolation pattern. In some cases, these and/or other characteristics can permit more freedom in designing the active area (e.g., a shape and/or size of the active area).

Advantages according to the present disclosure are not limited to the above-mentioned advantage. Other purposes and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims and combinations thereof.

According to an aspect of the present disclosure, there is provided an image sensor comprising: a substrate including a first face and a second face, the second face being opposite the first face in a first direction; a photoelectric conversion area disposed in the substrate; an active area disposed in the substrate and on the photoelectric conversion area; an element isolation pattern extending from the first face of the substrate into the substrate and defining the active area; and a transfer gate electrode including: a first portion extending from the first face of the substrate and extending through the element isolation pattern; and a second portion disposed on the active area, wherein the first portion extends through a bottom face of the element isolation pattern, wherein a vertical level of a bottom face of the first portion is lower than a vertical level of the bottom face of the element isolation pattern.

According to another aspect of the present disclosure, there is provided an image sensor comprising: a substrate including a first face and a second face opposite one another along a first direction; a photoelectric conversion area disposed in the substrate; an active area disposed in the substrate and on the photoelectric conversion area, wherein the active area includes a first sidewall and a second sidewall; an element isolation pattern disposed in the substrate and surrounding the active area; and a transfer gate electrode including: a first portion extending from the first face of the substrate and extending through the element isolation pattern, wherein the first portion includes a first sub-portion extending along the first sidewall, and a second sub-portion extending along the second sidewall; and a second portion on the active area, wherein the transfer gate electrode overlaps the photoelectric conversion area along the first direction and is non-overlapping with the photoelectric conversion area in a direction parallel to at least one of the first face or the second face of the substrate.

According to another aspect of the present disclosure, there is provided an image sensor comprising: a substrate including a first face and a second face opposite one another along a first direction; a pixel isolation pattern extending from the second face of the substrate into the substrate, wherein the pixel isolation pattern defines a plurality of pixels; at least one color filter disposed on the second face of the substrate; and at least one micro lens disposed on the color filter, wherein each of the plurality of pixels includes: a photoelectric conversion area disposed in the substrate; an active area disposed in the substrate and on the photoelectric conversion area; an element isolation pattern extending from the first face of the substrate into the substrate and contacting the pixel isolation pattern, wherein the element isolation pattern defines the active area; and a transfer gate electrode including: a first portion extending from the first face of the substrate and extending through the element isolation pattern; and a second portion disposed on the active area, wherein the first portion extends through a bottom face of the element isolation pattern, wherein a vertical level of a bottom face of the first portion is lower than a vertical level of the bottom face of the element isolation pattern.

Specific details of these and other implementations are included in detailed descriptions and drawings.

### BRIEF DESCRIPTION OF DRAWINGS

The above and other aspects and features of the present disclosure will become more apparent by describing in detail illustrative implementations thereof with reference to the attached drawings, in which:

FIG. 1 is a block diagram for illustrating an image sensing device according to some implementations;

FIG. 2 is an illustrative circuit diagram for illustrating a pixel of an image sensor according to some implementations;

FIG. 3 is an illustrative layout diagram for illustrating an image sensor according to some implementations;

FIGS. 4 and 5 are illustrative layout diagrams for illustrating a pixel of an image sensor according to some implementations;

FIG. 6 is a cross-sectional view taken along a line I-I of FIG. 5;

FIG. 7 to FIG. 10 are various schematic cross-sectional views for illustrating image sensors according to some implementations, respectively;

FIG. 11 to FIG. 14 are illustrative layout diagrams for illustrating a pixel of an image sensor according to some implementations;

FIG. 15 is an illustrative layout diagram for illustrating a pixel of an image sensor according to some implementations;

FIG. 16 to FIG. 18 are illustrative layout diagrams for illustrating a pixel of an image sensor according to some implementations;

FIG. 19 is a schematic cross-sectional view for illustrating an image sensor according to some implementations;

FIG. 20 is an illustrative perspective view of an image sensor in accordance with some implementations;

FIG. 21 is an illustrative perspective view of an image sensor in accordance with some implementations;

FIG. 22 to FIG. 28 are diagrams of intermediate structures corresponding to steps for illustrating a method for manufacturing an image sensor according to some implementations; and

FIG. 29 to FIG. 31 are diagrams of intermediate structures corresponding to steps for illustrating a method for manufacturing an image sensor according to some implementations.

### DETAILED DESCRIPTIONS

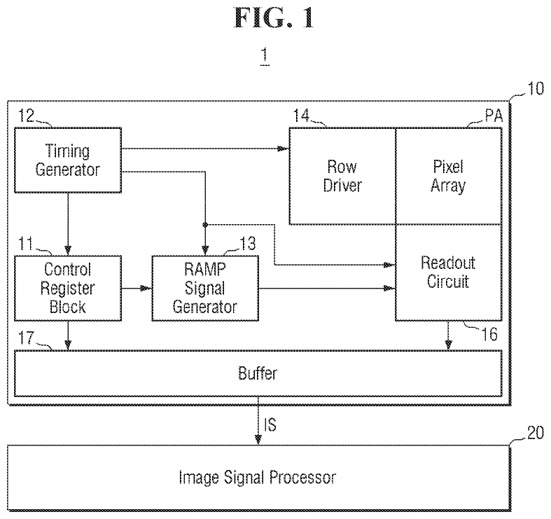

FIG. 1 is a block diagram for illustrating an image sensing device according to some implementations.

Referring to FIG. 1, an image sensing device 1 according to some implementations may include an image sensor 10 and an image signal processor 20.

The image sensor 10 may sense an image of a sensing target using light to generate an image signal IS. In some implementations, the generated image signal IS may be, for example, a digital signal. However, implementations according to the technical spirit of the present disclosure are not limited thereto.

The image signal IS may be provided to and processed by the image signal processor The image signal processor 20 may receive the image signal IS output from a buffer 17 of the image sensor 10 and process the received image signal IS for displaying thereof.

In some implementations, the image signal processor 20 may perform digital binning on the image signal IS output from the image sensor 10. In this case, the image signal IS output from the image sensor 10 may be a raw image signal from a pixel array PA not subjected to analog binning, or may be the image signal IS on which analog binning has already been performed.

In some implementations, the image sensor 10 and the image signal processor 20 may be disposed in a separate manner from each other as illustrated. For example, the image sensor may be mounted on a first chip, and the image signal processor 20 may be mounted on a second chip while the image sensor and the image signal processor may communicate with each other via a predefined interface. However, implementations are not limited thereto, and the image sensor 10 and the image signal processor 20 may be implemented into one package, for example, an MCP (multi-chip package).

The image sensor 10 may include a pixel array PA, a control register block 11, a timing generator 12, a row driver 14, a readout circuit 16, a ramp signal generator 13 and the buffer 17.

The control register block 11 may control an operation of the image sensor 10. For example, the control register block 11 may directly transmit an operation signal to the timing generator 12, the ramp signal generator 13 and/or the buffer 17.

The timing generator 12 may generate a signal as a reference for an operation timing of each of various components of the image sensor 10. The operation timing reference signal generated by the timing generator 12 may be transmitted to the ramp signal generator 13, the row driver 14, the readout circuit 16, and/or the like.

The ramp signal generator 13 may generate a ramp signal used in the readout circuit 16 and transmit the generated ramp signal to the readout circuit. For example, the readout circuit 16 may include a correlated double sampler (CDS), a comparator, etc., and the ramp signal generator 13 may generate the ramp signal used in the correlated double sampler, the comparator, and/or the like and transmit the generated ramp signal thereto.

The row driver 14 may selectively activate a row of the pixel array PA.

The pixel array PA may sense an external image. The pixel array PA may include a plurality of pixels arranged two-dimensionally (for example, in a matrix form).

The readout circuit 16 may sample a pixel signal provided from the pixel array PA, compare the sampled pixel signal with the ramp signal, and may convert an analog image signal data into a digital image signal (data) based on the comparison result.

The buffer 17 may include, for example, a latch. The buffer 17 may temporarily store therein the image signal IS to be provided to an external component, and may transmit the image signal IS to an external memory or an external device.

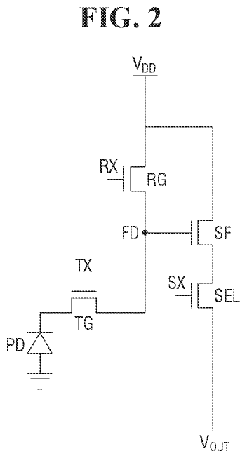

FIG. 2 is an illustrative circuit diagram for illustrating a pixel of an image sensor according to some examples.

Referring to FIG. 2, each pixel may include a photoelectric conversion element PD, a transfer transistor TG, a floating diffusion area FD, a reset transistor RG, a source follower transistor SF, and a select transistor SEL.

The photoelectric conversion element PD may generate electric charges in proportion to an amount of light incident from an outside. The photoelectric conversion element PD may be coupled with the transfer transistor TG that transfers the generated and accumulated charges to the floating diffusion area FD. The floating diffusion area FD may refer to an area that converts charges into voltage. Since the floating diffusion area FD has parasitic capacitance, charges may be accumulated therein.

One end of the transfer transistor TG may be connected to the photoelectric conversion element PD, and the other end of the transfer transistor TG may be connected to the floating diffusion area FD. The transfer transistor TG may be embodied as a transistor driven based on a predefined bias (for example, a transfer signal TX). That is, the transfer transistor TG may transfer the charges generated from the photoelectric conversion element PD to the floating diffusion area FD based on the transfer signal TX.

The source follower transistor SF may amplify change in an electrical potential of the floating diffusion area FD when the area FD has received the charges from the photoelectric conversion element PD, and then may output the amplified change to an output line VOUT. When the source follower transistor SF is turned on, a predefined electrical potential (for example, a power voltage VDD) provided to a drain of the source follower transistor SF may be transferred to a drain area of the select transistor SEL.

The select transistor SEL may select the pixel to be read on a row basis. The select transistor SEL may be embodied as a transistor driven using a select line that applies a predefined bias (for example, a row select signal SX).

The reset transistor RG may periodically reset the floating diffusion area FD. The reset transistor RG may be embodied as a transistor driven using a reset line that applies a predefined bias (for example, a reset signal RX).

When the reset transistor RG is tuned on based on the reset signal RX, a predefined electrical potential (for example, a power supply voltage VDD) provided to a drain of the reset transistor RG may be transferred to the floating diffusion area FD.

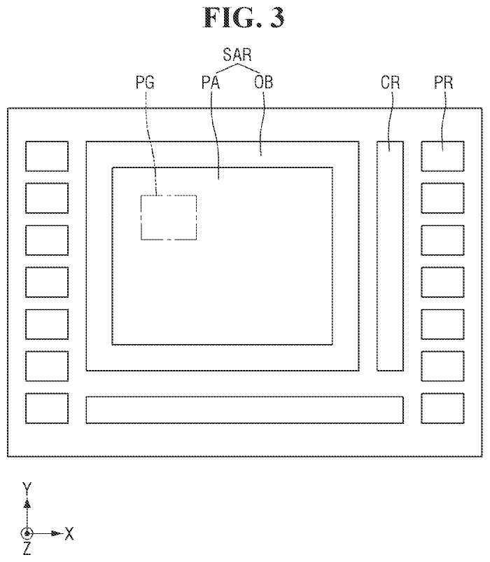

FIG. 3 is an illustrative layout diagram for illustrating an image sensor according to some implementations.

Referring to FIG. 3, the image sensor according to some implementations may include a sensor array area SAR, a connection area CR, and a pad area PR.

The sensor array area SAR may include an area corresponding to the pixel array PA of FIG. 1. The sensor array area SAR may include the pixel array PA and a light-blocking area OB. In the pixel array PA, active pixels for receiving light to generate an active signal may be arranged. Optical black pixels for blocking light to generate an optical black signal may be arranged in the light-blocking area OB. The light-blocking area OB may be formed around the pixel array PA in one example. However, this is merely an example. In some implementations, dummy pixels may be formed in a portion of the pixel array PA adjacent to the light-blocking area OB.

The connection area CR may be formed around (e.g., adjacent to or otherwise in proximity to) the sensor array area SAR. The connection area CR may be formed on one side of the sensor array area SAR. However, this is merely an example. Wirings may be formed in the connection area CR to transmit/receive an electrical signal of the sensor array area SAR.

The pad area PR may be formed around the sensor array area SAR. The pad area PR may be formed adjacent to an edge of the image sensor according to some implementations. However, this is merely an example. The pad area PR may be connected to an external device, etc. Thus, the image sensor according to some implementations and an external device may transmit/receive an electrical signal therebetween via the pad area PR.

In FIG. 3, the connection area CR is illustrated to be interposed between the sensor array area SAR and the pad area PR. However, this is only illustrative. In another example, an arrangement of the sensor array area SAR, the connection area CR, and the pad area PR may vary according to need.

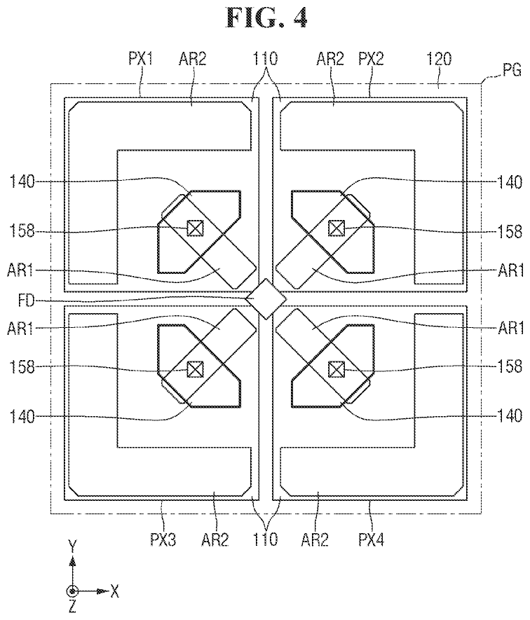

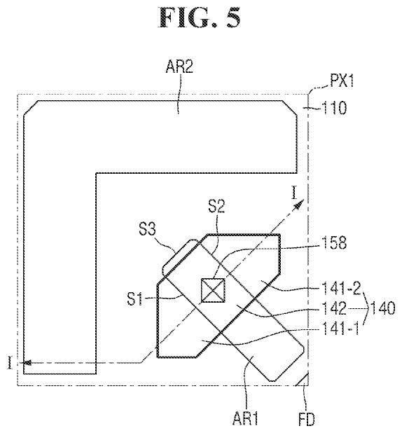

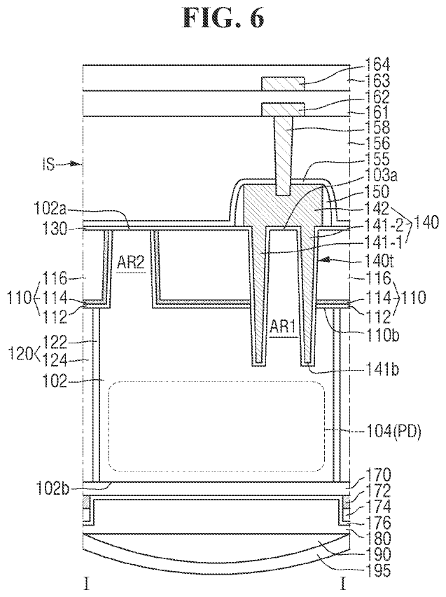

FIGS. 4 and 5 are illustrative layout diagrams for illustrating a pixel of an image sensor according to some implementations. FIG. 6 is a cross-sectional view taken along a line I-I of FIG. 5. For reference, FIG. 4 is an enlarged view of a PG portion of FIG. 3.

Referring to FIG. 2 and FIG. 4, the image sensor according to some implementations may include a pixel group PG. The pixel group PG may include, for example, first to fourth pixels PX1, PX2, PX3, and PX4 adjacent to each other.

For example, the first to fourth pixels PX1, PX2, PX3, and PX4 may be arranged in two rows and two columns. The first pixel PX1 may neighbor the third pixel PX3 in a second direction Y. The second pixel PX2 may neighbor the first pixel PX1 in a first direction X and may neighbor the fourth pixel PX4 in the second direction Y. The fourth pixel PX4 may neighbor the third pixel PX3 in the first direction X. Each of the first to fourth pixels PX1, PX2, PX3, and PX4 may be defined by an element isolation pattern 110. For example, the element isolation pattern 110 may surround each of the first to fourth pixels PX1, PX2, PX3, and PX4. The second direction Y may intersect the first direction X. For example, the second direction Y may be perpendicular to the first direction X. “Define,” as used herein, refers to at least partially defining. For example, the element isolation pattern 110 may, but need not, fully define the first to fourth pixels PX1, PX2, PX3, and PX4.

A pixel isolation pattern 120 may define each of first to fourth pixels PX1, PX2 PX3, PX4 in a first substrate 102. In some implementations, the pixel isolation pattern 120 may surround at least a portion of each of the first to fourth pixels PX1, PX2, PX3, and PX4. The pixel isolation pattern 120 may surround a portion of the floating diffusion area FD.

In one example, the first to fourth pixels PX1, PX2, PX3, and PX4 may share the floating diffusion area FD.

The floating diffusion area FD may be disposed in the first substrate 102. The floating diffusion area FD may be disposed in an active area defined by the element isolation pattern 110. The floating diffusion area FD may be formed, for example, by doping n-type impurities in the first substrate 102 of a p-type. The floating diffusion area FD may be disposed in a portion of each of the first to fourth pixels PX1, PX2, PX3, and PX4 while being shared by the first to fourth pixels PX1, PX2, PX3, and PX4. The floating diffusion area FD may be disposed in, for example, a corner of each of the first to fourth pixels PX1, PX2, PX3, and PX4. The floating diffusion area FD may be adjacent to or otherwise in proximity to a first active area AR1 of each of the first to fourth pixels PX1, PX2, PX3, and PX4.

The second pixel PX2 may be symmetrical with the first pixel PX1 with respect to the second direction Y. The third pixel PX3 may be symmetrical with the first pixel PX1 with respect to the first direction X. The fourth pixel PX4 may be symmetrical with the second pixel PX2 with respect to the first direction X. The fourth pixel PX4 may be symmetrical with the third pixel PX3 with respect to the second direction Y. Each of the second to fourth pixels PX2, PX3, and PX4 may be similar to the first pixel PX1. Hereinafter, the first pixel PX1 will be described in detail by way of example.

Referring to FIG. 5 and FIG. 6, the image sensor according to some implementations may include the first substrate 102, the element isolation pattern 110, the pixel isolation pattern 120, a gate dielectric film 130, a transfer gate electrode 140, a gate spacer 150, an etch stop film 155, a first wiring structure IS1, a grid pattern 172 and 174, a color filter 180 and a micro lens 190.

The first substrate 102 may be embodied as a semiconductor substrate. For example, the first substrate 102 may be made of bulk silicon or an SOI (silicon-on-insulator). The first substrate 102 may be embodied as a silicon substrate, and/or may include a material other than silicon, such as silicon germanium, indium antimonide, lead telluride compound, indium arsenide, indium phosphide, gallium arsenide or gallium antimonide. In some implementations, the first substrate 102 may include a base substrate and an epitaxial layer formed on the base substrate.

The first substrate 102 may include a first face 102a and a second face 102b opposite each other. In implementations as described below, the first face 102a may be referred to as a front face of the first substrate 102, and the second face 102b may be referred to as a rear face of the first substrate 102. In some implementations, the second face 102b of the first substrate 102 may act as a light receiving surface on which light is incident. That is, the image sensor according to some implementations may be a back side-illuminated (BSI) image sensor.

The first face 102a and the second face 102b may be opposite to each other in a third direction Z. In the third direction Z, the first face 102a may act as a top face of the first substrate 102 and the second face 102b may act as a bottom face of the first substrate 102. The third direction Z may intersect the first direction X and the second direction Y, e.g., may be orthogonal to the first direction X and the second direction Y. The first direction X and the second direction Y may define (e.g., together define a plane parallel to) the first face 102a and/or the second face 102b of the first substrate 102. The third direction Z may be a direction perpendicular to the first face 102a and/or the second face 102b of the first substrate 102. The third direction Z may be a direction from the second face 102b of the first substrate 102 toward the first face 102a thereof. In following descriptions, the top face and the bottom face may face each other in the third direction Z.

For example, the first substrate 102 may include p-type impurities such as boron (B), aluminum (Al), indium (In), or gallium (Ga).

A photoelectric conversion area 104 may be disposed in the first substrate 102 and in the first pixel PX1. The photoelectric conversion area 104 may correspond to the photoelectric conversion element PD of FIG. 2. That is, the photoelectric conversion area 104 may generate electric charges in proportion to an amount of light incident thereto from an outside.

For example, the photoelectric conversion area 104 may be formed by ion implantation of n-type impurities into the p-type first substrate 102.

The first pixel PX1 may include the first active area AR1 and a second active area AR2. The first active area AR1 and the second active area AR2 may be disposed in the first substrate 102 and on the photoelectric conversion area 104 (e.g., above the photoelectric conversion area 104 in the third direction Z). Each of the first active area AR1 and the second active area AR2 may extend from the first face 102a of the first substrate 102 into the first substrate 102. The first active area AR1 and the second active area AR2 may be spaced apart from each other. The first active area AR1 and the second active area AR2 may be isolated from each other by the element isolation pattern 110.

The element isolation pattern 110 may be disposed in the first substrate 102. The element isolation pattern 110 may extend from the first face 102a of the first substrate 102 into the first substrate 102. The element isolation pattern 110 may extend from the first face 102a of the first substrate 102 toward the second face 102b of the first substrate 102. For example, the element isolation pattern 110 may be formed by filling an insulating material into a shallow trench obtained by patterning a portion of the first substrate 102 including the first face 102a. The element isolation pattern 110 may surround (e.g., at least partially surround) the first active area AR1 and the second active area AR2. The element isolation pattern 110 may define the first active area AR1 and the second active area AR2.

The element isolation pattern 110 may be embodied as a multilayer. For example, the element isolation pattern 110 may include a first film 112, a second film 114, and a third film 116 that are sequentially stacked.

The first film 112 may extend along at least portion of a side face and a bottom face of the shallow trench formed by patterning the first substrate 102. The second film 114 may be disposed on the first film 112. The second film 114 may extend along with the first film 112. The third film 116 may be disposed on the second film 114. The third film 116 may fill a portion of the shallow trench remaining after the first film 112 and the second film 114 are disposed therein.

Each of the first film 112, the second film 114, and the third film 116 may include, for example, at least one of silicon oxide, silicon nitride, silicon oxynitride, and combinations thereof. However, the present disclosure is not limited thereto.

The second film 114 may include a material having an etch selectivity relative to a material of each of the first film 112 and the third film 116. For example, when each of the first film 112 and the third film 116 includes silicon oxide, the second film 114 may include at least one of silicon nitride, silicon carbonitride, silicon oxycarbonitride, and combinations thereof. In one example, the first film 112 and the third film 116 may include silicon oxide, and the second film 114 may include silicon nitride.

The pixel isolation pattern 120 may be disposed in the first substrate 102. The pixel isolation pattern 120 may define a plurality of pixels in the first substrate 102. For example, the pixel isolation pattern 120 may surround at least a portion of the first pixel PX1.

The pixel isolation pattern 120 may extend from a bottom face 110b of the element isolation pattern 110 toward (e.g., to) the second face 102b of the first substrate 102. The pixel isolation pattern 120 may contact the element isolation pattern 110. For example, a width of a top face of the pixel isolation pattern 120 may be smaller than a width of the bottom face 110b of the element isolation pattern 110. The pixel isolation pattern 120 may be formed, for example, by filling an insulating material into a deep trench formed by patterning the first substrate 102. The pixel isolation pattern 120 may include, for example, at least one of silicon oxide, silicon nitride, silicon oxynitride, and a combination thereof. However, the present disclosure is not limited thereto.

Although it is illustrated that a width of the pixel isolation pattern 120 is constant, this is only an example. In another example, the width of the pixel isolation pattern 120 may decrease as the pixel isolation pattern 120 extends toward the second face 102b of the first substrate 102. In still another example, the width of the pixel isolation pattern 120 may increase as the pixel isolation pattern 120 extends toward the second face 102b of the first substrate 102.

The pixel isolation pattern 120 may extend through an entirety of the first substrate 102. For example, a bottom face of the pixel isolation pattern 120 may be exposed at the second face 102b of the first substrate 102.

The pixel isolation pattern 120 may include a filling pattern 122 and a spacer film 124.

The filling pattern 122 may extend from the bottom face of the element isolation pattern 110 toward the second face 102b of the first substrate 102. The filling pattern 122 may include a conductive material, for example, polysilicon (polySi). However, the present disclosure is not limited thereto. In some implementations, a ground voltage or a negative voltage may be applied to the filling pattern 122. This filling pattern 122 may prevent electric charges generated due to ESD (electrostatic discharge) or the like from accumulating on a surface (for example, the second face 102b) of the first substrate 102, thereby effectively preventing ESD bruise defect.

The spacer film 124 may extend along a side face of the filling pattern 122. The spacer film 124 may include an insulating material, for example, at least one of silicon oxide, aluminum oxide, tantalum oxide, and combinations thereof. However, the present disclosure is not limited thereto. The spacer film 124 may be interposed between the filling pattern 122 and the first substrate 102 so as to electrically insulate the filling pattern 122 and the first substrate 102 from each other.

The transfer gate electrode 140 may be disposed on the first active area AR1 and the element isolation pattern 110. The transfer gate electrode 140 may correspond to a gate electrode of the transfer transistor (for example, the transfer transistor TG of FIG. 2). The transfer gate electrode 140 may overlap the photoelectric conversion area 104 in the third direction Z. The transfer gate electrode 140 may not overlap the photoelectric conversion area 104 in the first direction X and the second direction Y.

The transfer gate electrode 140 may be embodied as a vertical transfer gate electrode. At least a portion of the transfer gate electrode 140 may be embedded in the first substrate 102. The first substrate 102 may include a trench 140t extending from the first face 102a of the first substrate 102 into the first substrate 102. The trench 140t may extend through an entirety of the element isolation pattern 110 in the third direction Z. The transfer gate electrode 140 may fill the trench 140t.

The transfer gate electrode 140 may include first portions 141-1 and 141-2 extending from the first face 102a of the first substrate 102 into the first substrate 102, and a second portion 142 disposed on the first face 102a of the first substrate 102.

The first portions 141-1 and 141-2 may be disposed in the element isolation pattern 110. The first portions 141-1 and 141-2 may extend through an entirety of the element isolation pattern 110. Each of the first portions 141-1 and 141-2 may extend through the bottom face 110b of the element isolation pattern 110. A bottom face 141b of one or both of the first portions 141-1 and 141-2 may be positioned below the bottom face 110b of the element isolation pattern 110.

In some implementations, the element isolation pattern 110 may not be disposed between the first active area AR1 and the first portions 141-1 and 141-2.

The trench 140t may overlap one end of the shallow trench in which the element isolation pattern 110 is disposed. The trench 140t may extend through one end of the shallow trench. Accordingly, one sidewall of the trench 140t may define an entirety of one sidewall of the element isolation pattern 110, and the other sidewall of the trench 140t may define sidewalls S1 and S2 of the first active area AR1. For example, a portion of the trench 140t in which a first-first portion 141-1 is disposed may define the first sidewall S1 of the first active area AR1, while a portion of the trench 140t in which a first-second portion 141-2 is disposed may define the second sidewall S2 of the first active area AR1.

One sidewall of the element isolation pattern 110 on which the first portions 141-1 and 141-2 of the transfer gate electrode 140 are disposed may be defined by the trench 140t, while the other sidewall of the element isolation pattern 110, opposite to said one sidewall, may be defined by the first substrate 102. The first film 112 and the second film 114 may not extend along said one sidewall of the element isolation pattern 110 defined by the trench 140t, but may extend along the other sidewall of the element isolation pattern 110 defined by the first substrate 102. For example, the first film 112 and the second film 114 may not extend along the sidewall of the trench 140t, but may extend along a sidewall of the second active area AR2.

The second portion 142 may be disposed on the first active area AR1. The second portion 142 may extend along a top face 103a of the first active area AR1. The second portion 142 may connect the first-first portion 141-1 and the first-second portion 141-2 to each other. A portion of the first active area AR1 on which the second portion 142 is disposed may be disposed between the first-first portion 141-1 and the first-second portion 141-2. The second portion 142 may further extend, for example, along at least a portion of a top face of the element isolation pattern 110.

A top face of the transfer gate electrode 140 may be flat. A top face of the second portion 142 of the transfer gate electrode 140 may be flat. The top face 103a of the portion of the first active area AR1 on which the second portion 142 is disposed may have, for example, a rounded edge. This may be due to a process of etching the top face 103a of the first active area AR1.

In some implementations, the top face 103a of the portion of the first active area AR1 on which the second portion 142 is disposed may be substantially coplanar with the first face 102a of the first substrate 102. The top face 103a of the portion of the first active area AR1 on which the second portion 142 is disposed may be substantially coplanar with a top face of a portion of the first active area AR1 on which the second portion 142 is not disposed.

In some implementations, the first portions 141-1 and 141-2 of the transfer gate electrode 140 may be respectively disposed on the first and second sidewalls S1 and S2, and may be spaced apart from each other.

The first active area AR1 may include the first sidewall S1, the second sidewall S2 and a third sidewall S3. The first sidewall S1 and the second sidewall S2 may not be connected to each other. The third sidewall S3 may connect the first sidewall S1 and the second sidewall S2 to each other. For example, the first sidewall S1 and the second sidewall S2 may be opposite to each other. The first portions 141-1 and 141-2 may include the first-first portion 141-1 disposed on the first sidewall S1 and extending through the element isolation pattern 110 and the first-second portion 141-2 disposed on the second sidewall S2 and extending through the element isolation pattern 110. That is, the transfer gate electrode 140 may be disposed on both opposite sides of the first active area AR1.

The first active area AR1 may further include a sidewall connecting the first sidewall S1 and the third sidewall S3 to each other and a sidewall connecting the second sidewall S2 and the third sidewall S3 to each other. In some implementations, the first sidewall S1 and the third sidewall S3 may be directly connected to each other, and the second sidewall S2 and the third sidewall S3 may be directly connected to each other, so that the first active area AR1 may have a rectangular shape in a plan view.

The transfer gate electrode 140 may include, for example, at least one of polysilicon doped with impurities, metal silicide such as cobalt silicide, metal nitride such as titanium nitride, and/or metal such as tungsten, copper, and aluminum. However, the present disclosure is not limited thereto.

The gate dielectric film 130 may be interposed between the transfer gate electrode 140 and the first substrate 102. For example, in the first substrate 102, the trench 140t overlapping with at least a portion of the first active area AR1 and at least a portion of the element isolation pattern 110 may be defined. The trench 140t may extend from the first face 102a of the first substrate 102, and a bottom face of trench 140t may be disposed in the first substrate 102. The trench 140t may extend through the bottom face 110b of the element isolation pattern 110, and the bottom face of the trench 140t may be positioned below the bottom face 110b of the element isolation pattern 110. The gate dielectric film 130 may extend along a side face and the bottom face of the trench 140t. The transfer gate electrode 140 may be disposed on the gate dielectric film 130 so as to fill the trench 140t.

The gate dielectric film 130 may extend along the first face 102a of the first substrate 102. However, the present disclosure is not limited thereto. In another example, the gate dielectric film 130 may not extend along the first face 102a of the first substrate 102.

The gate dielectric film 130 may include, for example, at least one of silicon oxide, silicon nitride, silicon oxynitride, and/or a low-k material having a dielectric constant lower than that of silicon oxide. However, the present disclosure is not limited thereto. The low dielectric constant (low-k) material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SiLK, amorphous fluorinated carbon, silica aerogels, silica xerogels, mesoporous silica, or a combination thereof. The present disclosure is not limited thereto. In one example, the gate dielectric film 130 may include a silicon oxide film.

The gate spacer 150 may be disposed on the transfer gate electrode 140. The gate spacer 150 may be disposed on each of both opposing side faces of the transfer gate electrode 140. For example, at least a portion of the second portion 142 of the transfer gate electrode 140 may be disposed on the first face 102a of the first substrate 102. The gate spacer 150 may be disposed on each of both opposing side faces of the second portion 142 of the transfer gate electrode 140 on the first face 102a of the first substrate 102.

The gate spacer 150 may include, for example, at least one of silicon oxide, silicon nitride, silicon oxynitride, and combinations thereof. However, the present disclosure is not limited thereto. In one example, the gate spacer 150 may include a silicon nitride film.

The etch stop film 155 may extend along the gate spacer 150, a top face of the transfer gate electrode 140, and the gate dielectric film 130. The etch stop film 155 may include, for example, at least one of silicon nitride, silicon oxynitride, or silicon carbon nitride.

The first wiring structure IS1 may be formed on the first substrate 102. The first wiring structure IS1 may be formed, for example, on the first face 102a of the first substrate 102. For example, the first wiring structure IS1 may cover the first face 102a of the first substrate 102.

The first wiring structure IS1 may include one or more wirings. For example, the first wiring structure IS1 may include first wiring insulating films 156, 161, and 163, a contact 158, and first wirings 162 and 164. The number and the arrangement of layers of the first wirings 162 and 164 and the contact 158 constituting the first wiring structure IS1 are merely examples, and the technical spirit of the present disclosure is not limited thereto.

A first-first wiring insulating film 156 may cover the etch stop film 155. A first-second wiring insulating film 161 may be disposed on the first-first wiring insulating film 156. A first-third wiring insulating film 163 may be disposed on the first-second wiring insulating film 161. The contact 158 may be disposed in the first-first wiring insulating film 156, a first-first wiring 162 may be disposed in the first-second wiring insulating film 161, and a first-second wiring 164 may be disposed in the first-third wiring insulating film 163. The first wirings 162 and 164 may be electrically connected to the first pixel PX1. The first wirings 162 and 164 may be electrically connected to the transfer gate electrode 140 via the contact 158.

The contact 158 may be in contact with the transfer gate electrode 140. A portion of the contact 158 may extend into the transfer gate electrode 140, and a bottom face of the contact 158 may be disposed in the transfer gate electrode 140. However, the present disclosure is not limited thereto. For example, the contact 158 may be in contact with the top face of the transfer gate electrode 140.

Each of the first wiring insulating films 156, 161 and 163 may include, for example, at least one of silicon oxide, silicon nitride, silicon oxynitride, and a low-k material having a dielectric constant lower than that of silicon oxide. However, the present disclosure is not limited thereto.

A surface insulating film 170 may be disposed on the second face 102b of the first substrate 102. The surface insulating film 170 may extend along the second face 102b of the first substrate 102. The surface insulating film 170 may include an insulating material, for example, at least one of silicon oxide, silicon nitride, silicon oxynitride, aluminum oxide, hafnium oxide, and combinations thereof. However, the present disclosure is not limited thereto.

The surface insulating film 170 may be embodied as, for example, a multilayer. For example, the surface insulating film 170 may include an aluminum oxide film, a hafnium oxide film, a silicon oxide film, a silicon nitride film, and a hafnium oxide film sequentially stacked on the second face 102b of the first substrate 102.

The surface insulating film 170 may function as an antireflection film to prevent light incident on the second face 102b of the first substrate 102 from being reflected therefrom. Thus, a light receiving percentage of the photoelectric conversion area 101 may be improved. Further, the surface insulating film 170 may function as a planarization film, and thus may allow the color filter 180 and the micro lens 190 to be described later to be formed at a uniform vertical dimension.

The color filter 180 may be disposed on the surface insulating film 170. The color filter 180 may be disposed in a corresponding manner to each of pixels (for example, the first pixel PX1). That is, a plurality of color filters 180 may be arranged in a plane including the first direction X and the second direction Y two-dimensionally (for example, in a matrix form).

The color filter 180 may have various colors according to pixels. For example, the color filter 180 may include a red color filter, a green color filter, a blue color filter, a yellow color filter, a magenta color filter and/or a cyan color filter, and/or may further include a white filter.

The grid pattern 172 and 174 may be disposed on the surface insulating film 170. The grid pattern 172 and 174 may be formed in a grid manner in a plan view and may be interposed between the color filters 180. For example, the grid pattern 172 and 174 may overlap the pixel isolation pattern 120 in the third direction Z.

The grid pattern 172 and 174 may include a metal pattern 172 and a low refractive index pattern 174. The metal pattern 172 and the low refractive index pattern 174 may be sequentially stacked on, for example, the surface insulating film 170.

The metal pattern 172 may include, for example, at least one of titanium (Ti), titanium nitride (TiN), tantalum (Ta), tantalum nitride (TaN), tungsten (W), aluminum (Al), copper (Cu), and combinations thereof. However, the present disclosure is not limited thereto. The metal pattern 172 may prevent charges generated by ESD (electrostatic discharge) or the like from accumulating on the surface (for example, the second face 102b) of the first substrate 102, thereby effectively preventing ESD bruising defect.

The low refractive index pattern 174 may include a low refractive index material having a refractive index lower than that of silicon (S1). For example, the low refractive index pattern 174 may include at least one of silicon oxide, aluminum oxide, tantalum oxide, and combinations thereof. However, the present disclosure is not limited thereto. The low refractive index pattern 174 may refract or reflect light obliquely incident thereon to improve light condensing efficiency.

A first protective film 176 may be disposed on the surface insulating film 170 and the grid pattern 172 and 174. For example, the first protective film 176 may extend along the surface insulating film 170 and the grid pattern 172 and 174. The first protective film 176 may include, for example, aluminum oxide. However, the present disclosure is not limited thereto. The first protective film 176 may prevent damage to the surface insulating film 170 and the grid pattern 172 and 174.

The micro lens 190 may be disposed on the color filter 180. The micro lens 190 may be disposed in a corresponding manner to each of the pixels (for example, the first pixel PX1). For example, a plurality of micro lenses 190 may be arranged in a plane including the first direction X and the second direction Y two-dimensionally (for example, in a matrix form).

The micro lens 190 has a convex shape and may have a predefined radius of curvature. Accordingly, the micro lens 190 may condense the light incident on the photoelectric conversion area 104. The micro lens 190 may include, for example, a light-transmitting resin. However, the present disclosure is not limited thereto.

A second protective film 195 may be disposed on the micro lens 190. The second protective film 195 may extend along a surface of the micro lens 190. The second protective film 195 may include, for example, an inorganic oxide film. For example, the second protective film 195 may include at least one of silicon oxide, titanium oxide, zirconium oxide, hafnium oxide, and combinations thereof. However, the present disclosure is not limited thereto. In some implementations, the second protective film 195 may include low temperature oxide (LTO). The second protective film 195 may protect the micro lens 190 from an outside. For example, the second protective film 195 may include an inorganic oxide film to protect the micro lens 190 including an organic material. Further, the second protective film 195 may improve light condensing efficiency of the micro lens 190 to improve quality of the image sensor. For example, the second protective film 195 may fill a space between the micro lenses 190 to reduce reflection, refraction, scattering, etc. of incident light reaching the space between the micro lenses 190.

In one example, at least one of a gate electrode of the reset transistor RG, a gate electrode of the source follower transistor SF, a gate electrode of the select transistor SEL, and/or a ground area of FIG. 2 may be disposed on the second active area AR2. For example, referring to FIG. 4, the gate electrode of the reset transistor RG, the gate electrode of the source follower transistor SF, the gate electrode of the select transistor SEL, and the ground area may be disposed on the second active areas AR2 of the first to fourth pixels PX1, PX2, PX3, and PX4, respectively. A correspondence in which each of the gate electrode of the reset transistor RG, the gate electrode of the source follower transistor SF, the gate electrode of the select transistor SEL, and the ground area corresponds to which one of the second active areas AR2 of the first to fourth pixels of PX1, PX2, PX3, and PX4 may vary. In some implementations, the first pixel PX1 may include at least two of the gate electrode of the reset transistor RG, the gate electrode of the source follower transistor SF, and the gate electrode of the select transistor SEL.

Each of the gate electrode of the reset transistor RG, the gate electrode of the source follower transistor SF, and the gate electrode of the select transistor SEL may be embodied as a planar gate electrode. For example, a bottom face of the gate electrode thereof may extend along the first face 102a of the first substrate 102.

In the image sensor according to some implementations, a portion of the transfer gate electrode 140 may be formed in the trench defined by recessing the element isolation pattern 110. Thus, compared to a case in which the transfer gate electrode 140 is formed in the trench defined by recessing the first active area AR1, an area size of a portion in the first active area AR1 occupied with the transfer gate electrode 140 decreases. This is because only a size of the first active area AR1 defined between the first-first portion 141-1 and the first-second portion 141-2 is required. Accordingly, the design freedom of the active area (for example, the first and second active areas AR1 and AR2) in the first pixel PX1 may be improved.

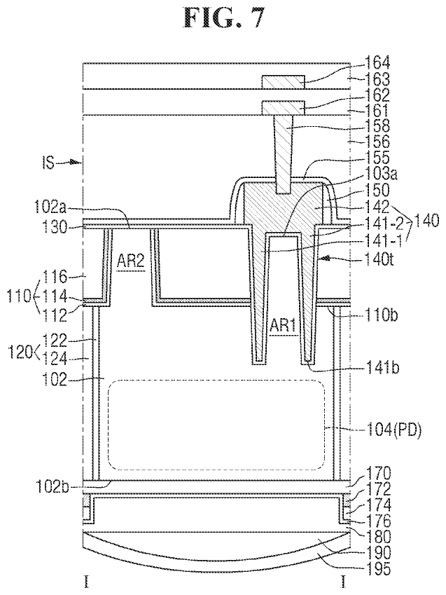

FIG. 7 to FIG. 10 are various schematic cross-sectional views for illustrating image sensors according to some implementations, respectively. For reference, FIG. 7 to FIG. 10 are cross-sectional views taken along a line I-I in FIG. 5. For convenience of description, components identical with those as described above using FIG. 1 to FIG. 6 are briefly described or omitted.

Referring to FIG. 7, in the image sensor according to some implementations, the top face 103a of the portion of the first active area AR1 on which the second portion 142 is disposed may be positioned below the first face 102a of the first substrate 102. A bottom face of the second portion 142 may be positioned below the top face of the element isolation pattern 110 or the first face 102a of the first substrate 102. The top face 103a of the portion of the first active area AR1 on which the second portion 142 is disposed may be positioned below the top face of the portion of the first active area AR1 on which the second portion 142 is not disposed.

Referring to FIG. 7, in some implementations, the top face 103a of the portion of the first active area AR1 on which the second portion 142 is disposed may be disposed above the bottom face 110b of the element isolation pattern 110.

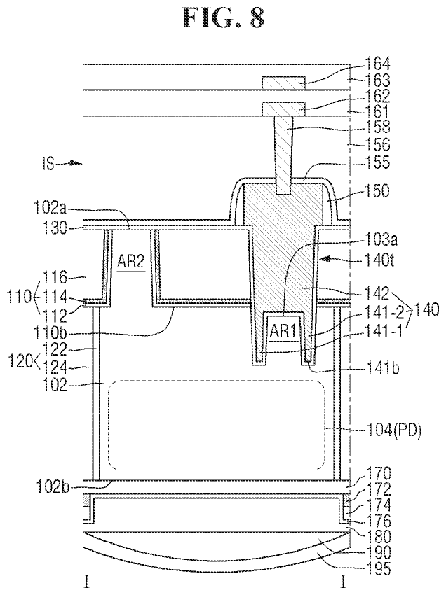

Referring to FIG. 8, in some implementations, the second portion 142 may extend through an entirety of the element isolation pattern 110. The top face 103a of the portion of the first active area AR1 on which the second portion 142 is disposed may be positioned below the bottom face 110b of the element isolation pattern 110. The bottom face of the second portion 142 may be positioned below the bottom face 110b of the element isolation pattern 110. The top face 103a of the portion of the first active area AR1 on which the second portion 142 is disposed may be disposed above the bottom face 141b of each of the first portions 141-1 and 141-2.

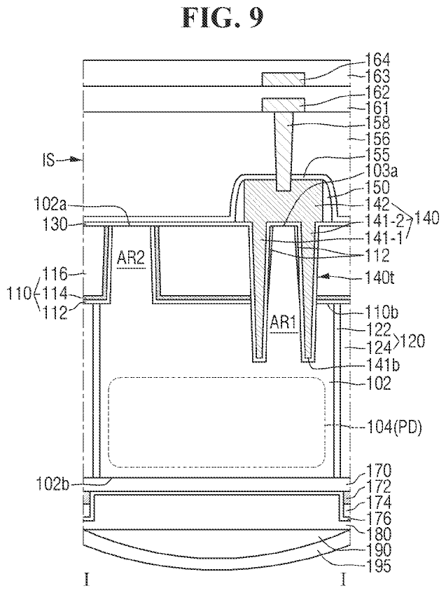

Referring to FIG. 9, in the image sensor according to some implementations, the element isolation pattern 110 may be disposed in at least a portion of an area between the first active area AR1 and the first portions 141-1 and 141-2.

The trench 140t may extend through a portion of one end of the shallow trench in which the element isolation pattern 110 is disposed. Accordingly, the trench 140t and the element isolation pattern 110 may define the first sidewall S1 and the second sidewall S2 of the first active area AR1. For example, a portion of the trench 140t in which the first-first portion 141-1 is disposed and the element isolation pattern 110 may define the first sidewall S1 of the first active area AR1, while a portion of the trench 140t in which the first-second portion 141-2 is disposed and the element isolation pattern 110 may define the second sidewall S2 of the first active area AR1.

In some implementations, the trench 140t may be adjacent to one end of the shallow trench in which the element isolation pattern 110 is disposed, but may not extend through one end of the shallow trench. The element isolation pattern 110 may be disposed in an entirety of an area between the first portions 141-1 and 141-2 extending through the element isolation pattern 110 and the first active area AR1.

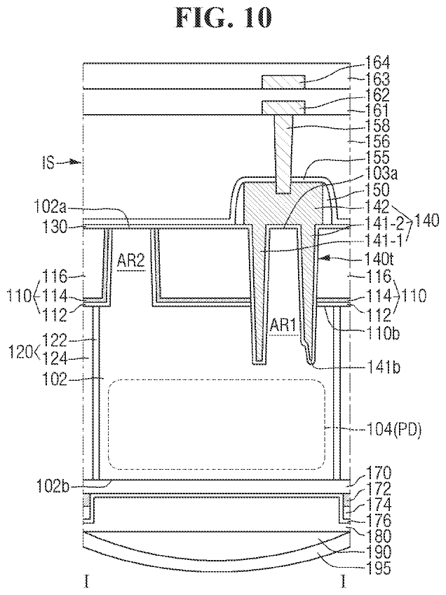

Referring to FIG. 10, in the image sensor according to some implementations, the bottom face 141b of each of the first portions 141-1 and 141-2 of the transfer gate electrode 140 may have a step. For example, a bottom face of the first-first portion 141-1 may not have a step, while the bottom face 141b of the first-second portion 141-2 may have a step. In some implementations, the bottom face of each of the first-first portion 141-1 and the bottom face 141b of the first-second portion 141-2 may have a step.

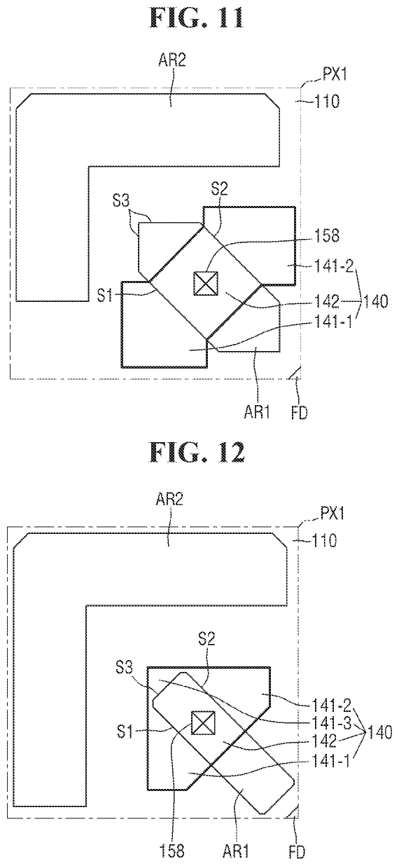

FIG. 11 to FIG. 14 are illustrative layout diagrams for illustrating a pixel of an image sensor according to some implementations. For convenience of description, components identical with those as described above using FIG. 1 to FIG. 10 are briefly described or omitted.

Referring to FIG. 11, in the image sensor according to some implementations, a shape of each of the first active area AR1 and the transfer gate electrode 140 in a plan view may vary. The first active area AR1 may further include a plurality of third sidewalls S3 connecting the first sidewall S1 and the second sidewall S2 to each other. For example, the first active area AR1 may include two third sidewalls S3 connecting the first sidewall S1 and the second sidewall S2 to each other.

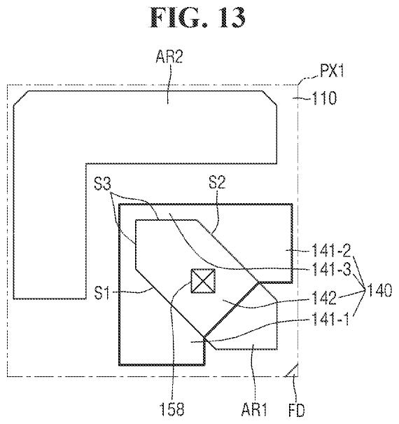

Referring to FIG. 12 and FIG. 13, the first portions 141-1 and 141-2 of the transfer gate electrode 140 may be disposed on the first to third sidewalls S1, S2, and S3 connected to each other, and may be connected to each other.

The first portions 141-1, 141-2, and 141-3 may further include a first-third portion 141-3 extending through the element isolation pattern 110 and disposed on the third sidewall S3. The first-third portion 141-3 may connect the first-first portion 141-1 and the first-second portion 141-2 to each other. The first portions 141-1, 141-2, and 141-3 may surround a portion of the first active area AR1. The first portions 141-1, 141-2, and 141-3 may be disposed on at least a portion of a combination of the first to third sidewalls S1, S2, and S3 connected to each other.

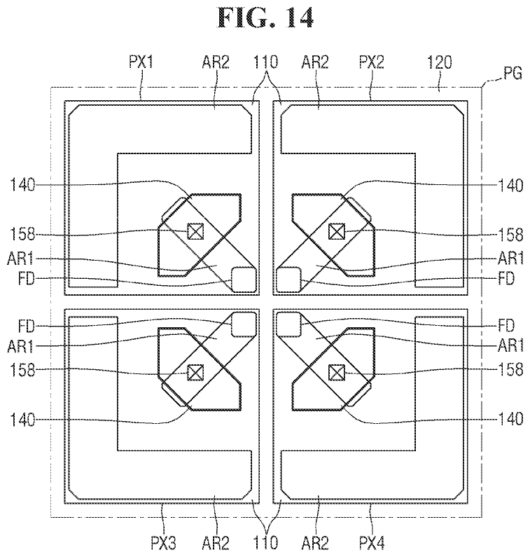

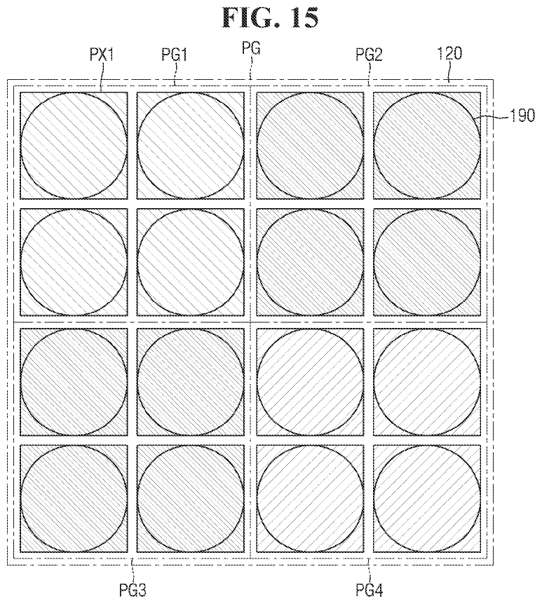

Referring to FIG. 14, in the image sensor according to some implementations, each of the first to fourth pixels PX1, PX2, PX3, and PX4 may include the floating diffusion area FD.

The floating diffusion area FD may be disposed in the first active area AR1 of each of the first to fourth pixels PX1, PX2, PX3, and PX4. The floating diffusion areas FD of the first to fourth pixels PX1, PX2, PX3, and PX4 may be spaced apart from each other in the first direction X or the second direction Y.

The pixel isolation pattern 120 may entirely isolate the first to fourth pixels PX1, PX2, PX3, and PX4 from each other. The pixel isolation pattern 120 may surround each of the first to fourth pixels PX1, PX2, PX3, and PX4.

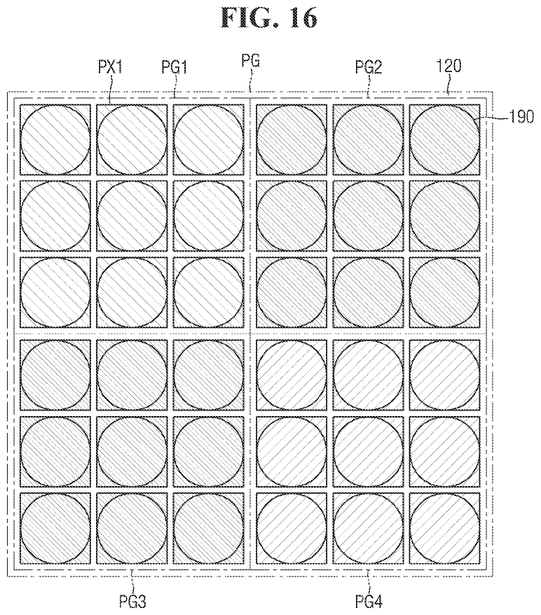

FIG. 15 is an illustrative layout diagram for illustrating a pixel of an image sensor according to some implementations. For convenience of description, components identical with those as described above using FIG. 1 to FIG. 14 are briefly described or omitted.

Referring to FIG. 15, a pixel group PG of the image sensor according to some implementations may include first to fourth pixel groups PG1, PG2, PG3, and PG4. Each of the first to fourth pixel groups PG1, PG2, PG3, and PG4 may include a plurality of first pixels PX1. For example, each of the first to fourth pixel groups PG1, PG2, PG3, and PG4 may include the first pixels PX1 arranged in two rows and two columns.

Color filters (for example, 180 in FIG. 6) disposed on the first to fourth pixel groups PG1, PG2, PG3, and PG4 may be arranged in a form of a Bayer pattern. For example, a color filter disposed on the first pixels PX1 of the first pixel group PG1 includes a first color filter. A color filter disposed on the first pixels PX1 of each of the second pixel group PG2 and the third pixel group PG3 includes a second color filter. A color filter disposed on the first pixels PX1 of the fourth pixel group PG4 may include a third color filter. For example, the first color filter may be a red color filter, the second color filter may be a green color filter, and the third color filter may be a blue color filter.

FIG. 16 to FIG. 18 are illustrative layout diagrams for illustrating a pixel of an image sensor according to some implementations. For convenience of description, components identical with those as described above using FIG. 1 to FIG. 15 are briefly described or omitted.

Referring to FIG. 16, in the image sensor according to some implementations, each of the first to fourth pixel groups PG1, PG2, PG3, and PG4 may include the first pixels PX1 arranged in three rows and three columns.

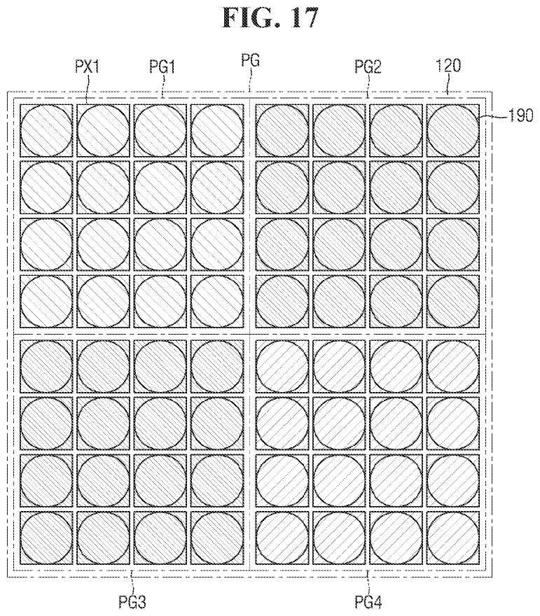

Referring to FIG. 17, in the image sensor according to some implementations, each of the first to fourth pixel groups PG1, PG2, PG3, and PG4 may include the first pixels PX1 arranged in four rows and four columns.

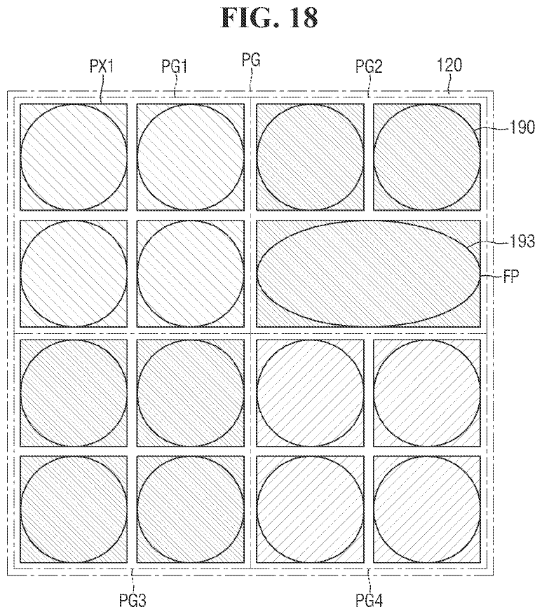

Referring to FIG. 18, the image sensor according to some implementations may include a focus pixel FP. The number and an arrangement of the focus pixels FP are merely examples, and the technical spirit of the present disclosure is not limited thereto.

The focus pixel FP may include two sub-pixels. The focus pixel FP may perform an AF (auto focus) function. The auto focus function may be performed using Phase detection AF (PDAF) using the sub-pixel. The sub-pixel may have a structure similar to that of the first pixel PX1. The micro lens 193 may be disposed in a corresponding manner to the focus pixel FP.

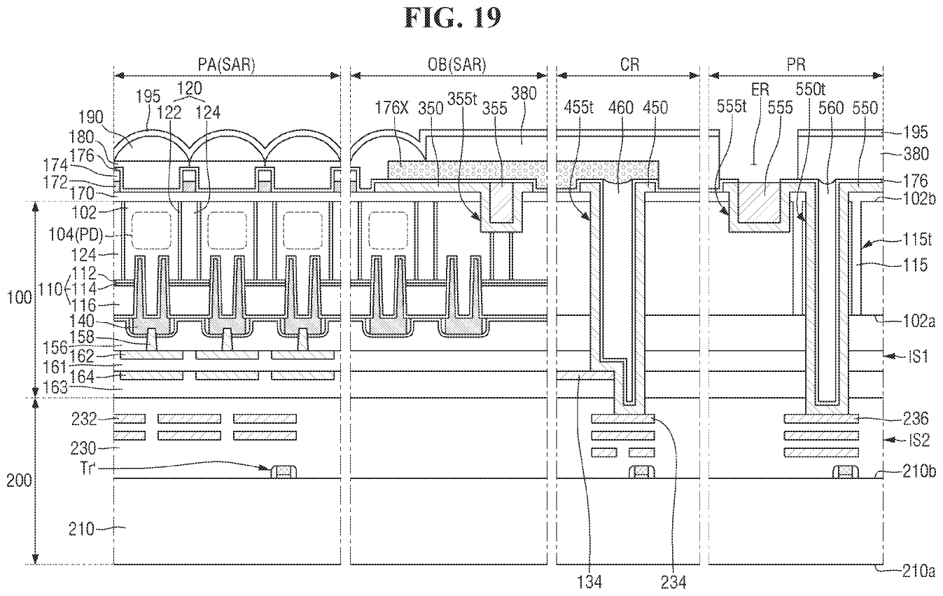

FIG. 19 is a schematic cross-sectional view for illustrating an image sensor according to some implementations. For convenience of description, components identical with those as described above using FIG. 1 to FIG. 18 are briefly described or omitted. In FIG. 19, the cross-sectional view of FIG. 6 is illustrated as a cross-sectional view of the sensor array area SAR by way of example.

The image sensor according to some implementations may include a first substrate structure 100 and a second substrate structure 200. The first substrate structure 100 may include the first substrate 102 and the first wiring structure IS1, and the second substrate structure 200 may include a second substrate 210 and a second wiring structure IS2.

The first wiring structure IS1 may include the first wirings 162 and 164 in the sensor array area SAR and a second wiring 134 in the connection area CR. The first wirings 162 and 164 may be electrically connected to the pixels of the sensor array area SAR. At least a portion of the second wiring 134 may be electrically connected to at least a portion of each of the first wirings 162 and 164. Thus, the second wiring 134 may be electrically connected to the pixels of the sensor array area SAR.

The second substrate 210 may be made of bulk silicon or SOI (silicon-on-insulator). The second substrate 210 may be embodied as a silicon substrate, or may include a material other than silicon, for example, silicon germanium, indium antimonide, lead telluride, indium arsenide, indium phosphide, gallium arsenide or gallium antimonide. In some implementations, the second substrate 210 may include the base substrate and an epitaxial layer formed on the base substrate.

The second substrate 210 may include a third face 210a and a fourth face 210b opposite to each other. In some implementations, the fourth face 210b of the second substrate 210 may face the first face 102a of the first substrate 102.

A plurality of electronic elements may be formed on the second substrate 210. For example, a transistor Tr′ may be formed on the fourth face 210b of the second substrate 210. The transistor Tr′ may be electrically connected to the sensor array area SAR, and may transmit and receive an electrical signal to and from the sensor array area SAR. For example, the transistor Tr′ may include electronic elements constituting the control register block 11, the timing generator 12, the ramp signal generator 13, the row driver 14, the readout circuit 16, etc. of FIG. 2.

The second wiring structure IS2 may be disposed on the second substrate 210. The second wiring structure IS2 may be formed, for example, on the fourth face 210b of the second substrate 210. The second wiring structure IS2 may be attached to the first wiring structure IS1. For example, a top face of the second wiring structure IS2 may be attached to a bottom face of the first wiring structure IS1.

The second wiring structure IS2 may include one or a plurality of wirings. For example, the second wiring structure IS2 may include a second wiring insulating film 230 and a plurality of wirings 232, 234, and 236 in the second wiring insulating film 230. In FIG. 19, the number of layers and arrangement of wirings constituting the second wiring structure IS2 are merely examples. The present disclosure is not limited thereto.

At least some of the wirings 232, 234, and 236 of the second wiring structure IS2 may be connected to the transistor Tr′. In some implementations, the second wiring structure IS2 may include the third wiring 232 in the sensor array area SAR, the fourth wiring 234 in the connection area CR, and the fifth wiring 236 in the pad area PR. In some implementations, the fourth wiring 234 may be a topmost wiring of a plurality of wirings in the connection area CR, and the fifth wiring 236 may be a topmost wiring of a plurality of wirings in the pad area PR.

The image sensor according to some implementations may include a first connection structure 350, a second connection structure 450, and a third connection structure 550.

The first connection structure 350 may be disposed in the light-blocking area OB. The first connection structure 350 may be disposed on the surface insulating film 170 of the light-blocking area OB. In some implementations, the first connection structure 350 may contact the pixel isolation pattern 120. For example, a first trench 355t exposing the pixel isolation pattern 120 may be formed in the first substrate 102 and the surface insulating film 170 and in the light-blocking area OB. The first connection structure 350 may be disposed in the first trench 355t so as to contact the pixel isolation pattern 120 in the light-blocking area OB. In some implementations, the first connection structure 350 may extend along profiles of a side face and a bottom face of the first trench 355t.

In some implementations, the first connection structure 350 may be electrically connected to the pixel isolation pattern 120 and may apply a ground voltage or a negative voltage to the pixel isolation pattern 120.

The first connection structure 350 may include, for example, at least one of titanium (Ti), titanium nitride (TiN), tantalum (Ta), tantalum nitride (TaN), tungsten (W), aluminum (Al), copper (Cu), and combinations thereof. However, the present disclosure is not limited thereto.

In some implementations, a first pad 355 filling the first trench 355t may be disposed on the first connection structure 350. The first pad 355 may include, for example, at least one of tungsten (W), copper (Cu), aluminum (Al), gold (Au), silver (Ag), and alloys thereof. However, the present disclosure is not limited thereto.

In some implementations, the first protective film 176 may cover the first connection structure 350 and the first pad 355. For example, the first protective film 176 may extend along profiles of the first connection structure 350 and the first pad 355.

The second connection structure 450 may be disposed in the connection area CR. The second connection structure 450 may be disposed on the surface insulating film 170 and in the connection area CR. The second connection structure 450 may electrically connect the first substrate structure 100 and the second substrate structure 200 to each other. For example, a second trench 455t exposing the second wiring 134 and the fourth wiring 234 may be formed in the first substrate structure 100 and the second substrate structure 200 and in the connection area CR. The second connection structure 450 may be disposed in the second trench 455t so as to connect the second wiring 134 and the fourth wiring 234 to each other. In some implementations, the second connection structure 450 may extend along profiles of a side face and a bottom face of the second trench 455t.

The second connection structure 450 may include, for example, at least one of titanium (Ti), titanium nitride (TiN), tantalum (Ta), tantalum nitride (TaN), tungsten (W), aluminum (Al), copper (Cu), and combinations thereof. However, the present disclosure is not limited thereto. In some implementations, the second connection structure 450 and the first connection structure 350 may be positioned at the same vertical level.

In some implementations, the first protective film 176 may cover the second connection structure 450. For example, the first protective film 176 may extend along a profile of the second connection structure 450.

In some implementations, a first filling insulating film 460 filling the second trench 455t may be disposed on the second connection structure 450. The first filling insulating film 460 may include, for example, at least one of silicon oxide, aluminum oxide, tantalum oxide, and combinations thereof. However, the present disclosure is not limited thereto.

The third connection structure 550 may be disposed in the pad area PR. The third connection structure 550 may be disposed on the surface insulating film 170 and in the pad area PR. The third connection structure 550 may be electrically connected to the second substrate structure 200 and an external device to each other.

For example, a third trench 550t exposing the fifth wiring 236 may be formed in the first substrate structure 100 and the second substrate structure 200 and in the pad area PR. The third connection structure 550 may be disposed in the third trench 550t and contact the fifth wiring 236. Further, a fourth trench 555t may be formed in a portion of the first substrate 102 of the pad area PR. The third connection structure 550 may be disposed in the fourth trench 555t so as to be exposed. In some implementations, the third connection structure 550 may extend along profiles of side faces and bottom faces of the third trench 550t and the fourth trench 555t.

The third connection structure 550 may include, for example, at least one of titanium (Ti), titanium nitride (TiN), tantalum (Ta), tantalum nitride (TaN), tungsten (W), aluminum (Al), copper (Cu), and combinations thereof. However, the present disclosure is not limited thereto. In some implementations, the first connection structure 350, the second connection structure 450, and the third connection structure 550 may be positioned at the same vertical level.

In some implementations, a second filling insulating film 560 filling the third trench 550t may be disposed on the third connection structure 550. The second filling insulating film 560 may include, for example, at least one of silicon oxide, aluminum oxide, tantalum oxide, and combinations thereof. However, the present disclosure is not limited thereto. In some implementations, the second filling insulating film 560 may be positioned at the same vertical level as a vertical level of the first filling insulating film 460.

In some implementations, a second pad 555 filling the fourth trench 555t may be disposed on the third connection structure 550. The second pad 555 may include, for example, at least one of tungsten (W), copper (Cu), aluminum (Al), gold (Au), silver (Ag), and alloys thereof. However, the present disclosure is not limited thereto. In some implementations, the second pad 555 may be positioned at the same vertical level as a vertical level of the first pad 355.

In some implementations, the first protective film 176 may cover the third connection structure 550. For example, the first protective film 176 may extend along a profile of the third connection structure 550. In some implementations, the first protective film 176 may expose the second pad 555.

In some implementations, a light-blocking color filter 170X may be disposed on the first connection structure 350 and the second connection structure 450. For example, the light-blocking color filter 170X may be formed to cover a portion of the first protective film 176 in each of the light-blocking area OB and the connection area CR. The light-blocking color filter 170X may include, for example, a blue color filter. However, the present disclosure is not limited thereto.

In some implementations, a third protective film 380 may be disposed on the light-blocking color filter 170X. For example, the third protective film 380 may be formed to cover a portion of the first protective film 176 in each of the light-blocking area OB, the connection area CR, and the pad area PR. In some implementations, the second protective film 195 may extend along a surface of the third protective film 380. The third protective film 380 may include, for example, a light-transmitting resin. However, the present disclosure is not limited thereto. In some implementations, the third protective film 380 may include the same material as that of the micro lens 190.

In some implementations, the second protective film 195 and the third protective film 380 may expose the second pad 555. For example, an exposure opening ER exposing the second pad 555 may be defined in the second protective film 195 and the third protective film 380. Accordingly, the second pad 555 may be connected to an external device, etc. Thus, the image sensor according to some implementations and the external device may transmit and receive an electrical signal therebetween via the second pad 555. That is, the second pad 555 may act as an input/output pad of the image sensor according to some implementations.

In some implementations, an isolation pattern 115 may be disposed in the first substrate 102. For example, an isolation trench 115t may be formed in the first substrate 102. The isolation pattern 115 may be disposed in the isolation trench 115t. It is illustrated that the isolation pattern 115 is formed only adjacent to the second connection structure 450 and the third connection structure 550. However, this is only an example. In another example, the isolation pattern 115 may be formed adjacent to the first connection structure 350. The isolation pattern 115 may include, for example, at least one of silicon oxide, silicon nitride, silicon oxynitride, aluminum oxide, hafnium oxide, and combinations thereof. However, the present disclosure is not limited thereto.

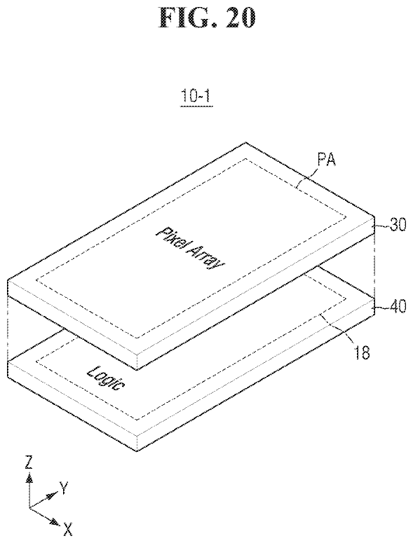

FIG. 20 is an illustrative perspective view of an image sensor in accordance with some implementations.

Referring to FIG. 1 and FIG. 20, an image sensor 10-1 according to some implementations may include a stack of a first layer 30 and a second layer 40. The first layer may be disposed on a top face of the second layer 40 and may be electrically connected to the second layer 40.

The first layer 30 may include the pixel array PA in which a plurality of pixels are arranged in a two-dimensional array structure.

The second layer 40 may include a logic area 18 in which logic elements are disposed. The logic elements included in the logic area 18 may be electrically connected to the pixel array PA, and may provide a signal to the pixel or process a signal output from the pixel. The logic elements included in the logic area 18 may include, for example, the control register block 11, the timing generator 12, the ramp signal generator 13, the row driver 14, the readout circuit 16, and the like.

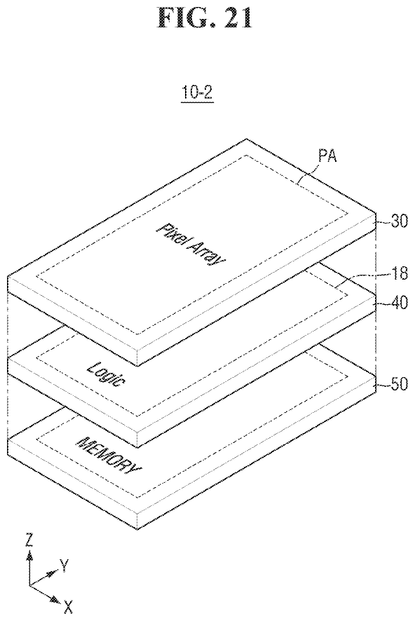

FIG. 21 is an illustrative perspective view of an image sensor in accordance with some implementations. For convenience of description, following description is based on differences thereof from those as described above using FIG. 20.

Referring to FIG. 21, an image sensor 10-2 according to some implementations may include the first layer 30, the second layer 40, and a third layer 50. The first layer 30 may be disposed on the second layer 40, and the second layer 40 may be disposed on the third layer 50.

The third layer 50 may include a memory device. For example, the third layer 50 may include a volatile memory device such as DRAM and SRAM. The third layer 50 may receive a signal from the first layer 30 and the second layer 40 and process the signal using the memory device disposed therein. That is, the image sensor 10-2 may be a three-stack image sensor including the three layers 30, 40, and 50.

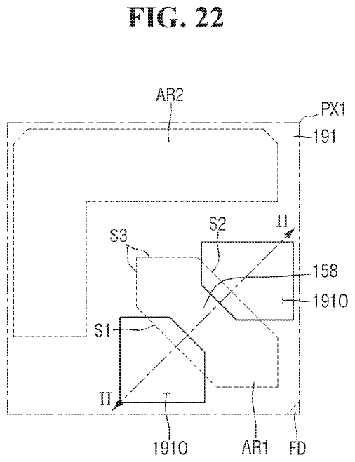

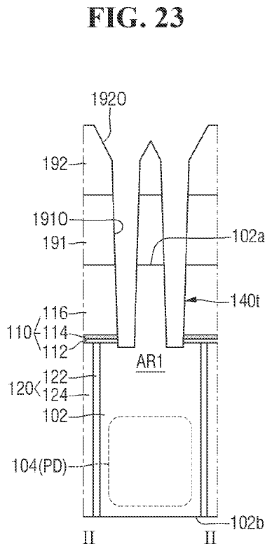

FIG. 22 to FIG. 28 are diagrams of intermediate structures corresponding to steps for illustrating a method for manufacturing an image sensor according to some implementations. For reference, FIG. 23 to FIG. 28 are cross-sectional views taken along a line II-II of FIG. 22. For convenience of description, components identical with those as described above using FIG. 1 to FIG. 19 are briefly described or omitted.

Referring to FIG. 22 and FIG. 23, the first substrate 102 including the first face 102a and the second face 102b opposite to each other may be provided. The photoelectric conversion area 104 may be formed in the first substrate 102. The element isolation pattern 110 defining the first active area AR1 and the second active area AR2 may be formed in the first substrate 102. The pixel isolation pattern 120 defining a pixel (for example, the first pixel PX1) may be formed in the first substrate 102.

A first mask 191 and a second mask 192 may be sequentially formed on the second face 102b of the first substrate 102. The second mask 192 may include an opening 1920. The second mask 192 may be, for example, an SOH (Spin-on Hardmask). The first mask 191 may include, for example, silicon oxynitride.

Subsequently, the first mask 191 and the element isolation pattern 110 may be etched using the second mask 192 including the opening 1920. Accordingly, the first mask 191 may include an opening 1910, and the trench 140t extending through the element isolation pattern 110 may be formed. Further, a portion of the first substrate 102 may be etched so that a bottom face of the trench 140t may be disposed in the first substrate 102.

At this time, an upper portion of the second mask 192 may be partially removed. Accordingly, a slope of the upper portion of the opening 1920 of the second mask 192 and a slope of a lower portion of the opening 1920 of the second mask 192 may be different from each other.

The second mask 192 may then be removed.

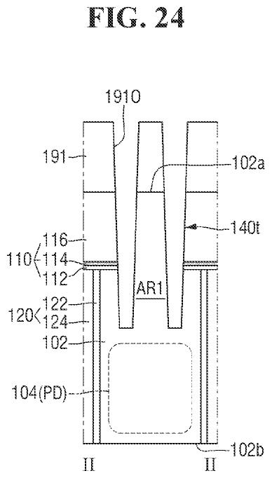

Referring to FIG. 24, the first substrate 102 may be further etched using the first mask 191. Accordingly, the trench 140t may further extend into the first substrate 102. A spacing between a bottom face of the trench 140t and the photoelectric conversion area 104 may be further reduced.

The first mask 191 may then be removed. Accordingly, the top face 103a of the first active area AR1 may be substantially coplanar with the first face 102a of the first substrate 102.

In this regard, a width of the trench 140t, a slope of the trench 140t, a depth of the trench 140t, a width of the first active area AR1 between spaced trenches 140t, etc. may vary based on a thickness of each of the first mask 191 and the second mask 192, a ratio of an etch rate of the first substrate 102 and an etch rate of the element isolation pattern 110, etc.

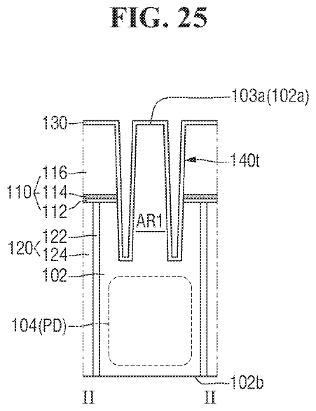

Referring to FIG. 25, the gate dielectric film 130 may be formed in the trench 140t. The gate dielectric film 130 may extend along a side face and a bottom face of the trench 140t. The gate dielectric film 130 may extend along the first face 102a of the first substrate 102 and the top face 103a of the first active area AR1.

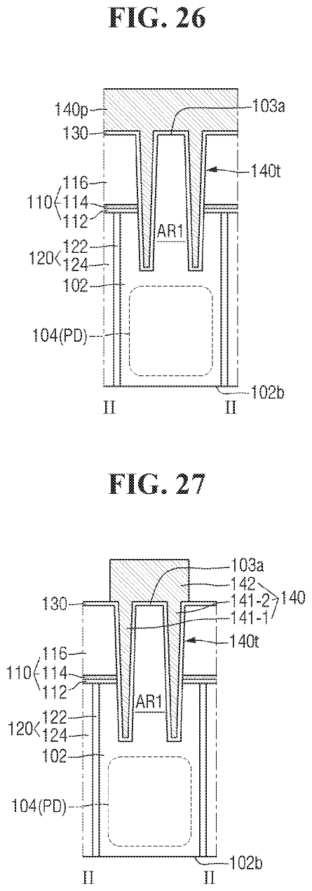

Referring to FIG. 26, a pre-transfer gate electrode 140p may be formed on the gate dielectric film 130. The pre-transfer gate electrode 140p may fill the trench 140t.

Referring to FIG. 27, the pre-transfer gate electrode 140p may be patterned to form the transfer gate electrode 140. Accordingly, the transfer gate electrode 140 including the first portions 141-1 and 141-2 filling the trench 140t and the second portion 142 disposed on the first active area AR1 may be formed. In the patterning process of the pre-transfer gate electrode 140p, the second portion 142 may extend along at least a portion of a top face of the element isolation pattern 110.

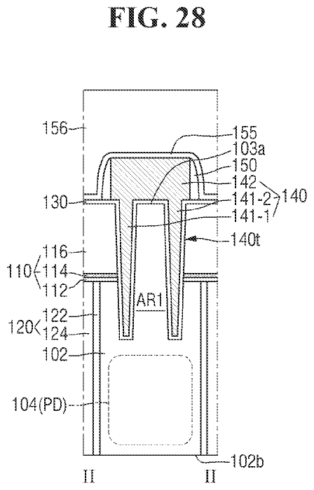

Referring to FIG. 28, the gate spacer 150 may be formed on a side face of the transfer gate electrode 140. The gate spacer 150 may be formed on a side face of the second portion 142.

Subsequently, the etch stop film 155 extending along the gate spacer 150, a top face of the transfer gate electrode 140, and a portion of the gate dielectric film 130 non-overlapping the gate spacer 150 and the transfer gate electrode 140 may be formed.

Then, referring to FIG. 6, the first wiring structure IS1 may be formed on the etch stop film 155. The first-first wiring insulating film 156 covering the etch stop film 155 may be formed, and then, the contact 158 extending through the first-first wiring insulating film 156 and contacting the transfer gate electrode 140 may be formed. The first-second wiring insulating film 161 and the first-first wiring 162 may be formed on the first-first wiring insulating film 156. The first-third wiring insulating film 163 and the first-second wiring 164 may be formed on the first-second wiring insulating film 161.

Subsequently, the surface insulating film 170, the grid pattern 172 and 174, the color filter 180, and the micro lens 190 may be sequentially formed on the second face 102b of the first substrate 102.

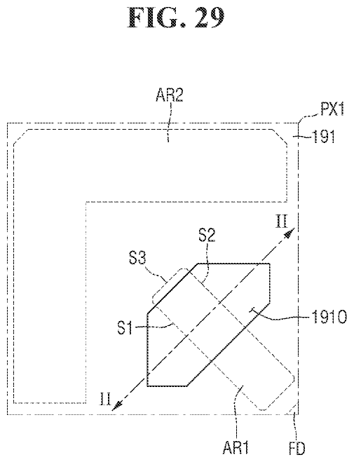

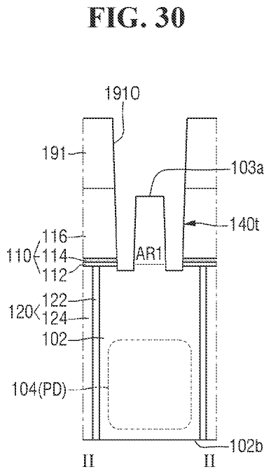

FIG. 29 to FIG. 31 are diagrams of intermediate structures corresponding to steps for illustrating a method for manufacturing an image sensor according to some implementations. For reference, FIG. 29 to FIG. 31 are cross-sectional views taken along a line II-II of FIG. 29. For convenience of description, components identical with those as described above using FIG. 1 to FIG. 19 are briefly described or omitted.

Referring to FIG. 29, the first mask 191 including the opening 1910 may be formed on the second face 102b of the first substrate 102. The element isolation pattern 110 may be etched using the first mask 191. Accordingly, the trench 140t extending through the element isolation pattern 110 may be formed. Further, a portion of the first substrate 102 may be etched. Accordingly, a bottom face of the trench 140t may be disposed in the first substrate 102.

At this time, a portion of the first active area AR1 may be etched together. Accordingly, the top face 103a of the first active area AR1 may be positioned below a top face of the element isolation pattern 110.

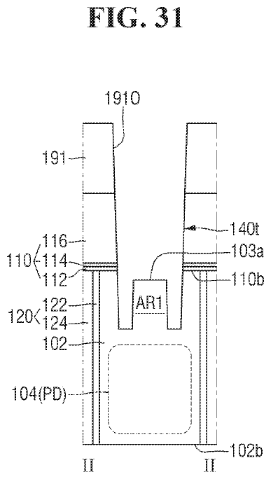

Referring to FIG. 31, an etch back process may be performed using the first mask 191 such that the first active area AR1 and a portion of the first substrate 102 exposed through the trench 140t may be further etched. Accordingly, the trench 140t may further extend into the first substrate 102, and a spacing between a bottom face of the trench 140t and the photoelectric conversion area 104 may be further reduced. Further, the top face 103a of the first active area AR1 may be positioned below the bottom face 110b of the element isolation pattern 110.

The first mask 191 may then be removed. Then, using the manufacturing process as described using FIG. 25 to FIG. 28, the image sensor using described above with reference to FIG. 8 may be manufactured.

Although some implementations of the present disclosure have been described above with reference to the accompanying drawings, the present disclosure is not limited to the above implementations, but may be implemented in various different forms. A person skilled in the art will be able to appreciate that the present disclosure may be embodied in other concrete forms without changing the technical spirit or essential characteristics of the present disclosure. Therefore, it should be understood that the implementations as described above are not restrictive but illustrative in all respects.

1. An image sensor comprising:
a substrate including a first face and a second face, the second face being opposite the first face in a first direction;
a photoelectric conversion area disposed in the substrate;
an active area disposed in the substrate and on the photoelectric conversion area;
an element isolation pattern extending from the first face of the substrate into the substrate and defining the active area; and
a transfer gate electrode including:
a first portion extending from the first face of the substrate and extending through the element isolation pattern; and
a second portion disposed on the active area,
wherein the first portion extends through a bottom face of the element isolation pattern, and
wherein a vertical level of a bottom face of the first portion is lower than a vertical level of the bottom face of the element isolation pattern.

2. The image sensor of claim 1,
wherein the first portion of the transfer gate electrode includes a first sub-portion extending through the element isolation pattern and a second sub-portion extending through the element isolation pattern,
wherein the first portion of the transfer gate electrode extends along a first sidewall of the active area and the second portion of the transfer gate electrode extends along a second sidewall of the active area, the first sidewall being opposite the second sidewall, and
wherein the second portion of the transfer gate electrode connects the first sub-portion and the second sub-portion to one another.

3. The image sensor of claim 1, wherein a vertical level of a top face of the active area is lower than a vertical level of the first face of the substrate.

4. The image sensor of claim 1, wherein a vertical level of a top face of the active area is lower than the vertical level of the bottom face of the element isolation pattern.

5. The image sensor of claim 1, wherein a sidewall of the first portion includes a first sidewall and a second sidewall opposite one another,
wherein the first sidewall is defined in a first portion of a trench and the second sidewall is defined in a second portion of the trench, and
wherein the element isolation pattern is disposed adjacent to the first portion of the trench and spaced apart from the second portion of the trench.

6. The image sensor of claim 1, wherein the element isolation pattern is disposed between the first portion and the active area.

7. The image sensor of claim 1, wherein the bottom face of the first portion of the transfer gate electrode has a step.

8. The image sensor of claim 1, wherein the element isolation pattern includes a first film, a second film, and a third film stacked sequentially on one another, and
wherein the first film and the second film do not extend along a sidewall of the first portion.

9. The image sensor of claim 1, wherein the photoelectric conversion area overlaps the transfer gate electrode along the first direction and is non-overlapping with the transfer gate electrode along a second direction orthogonal to the first direction.

10.-11. (canceled)

12. An image sensor comprising:
a substrate including a first face and a second face opposite one another along a first direction;
a photoelectric conversion area disposed in the substrate;
an active area disposed in the substrate and on the photoelectric conversion area, wherein the active area includes a first sidewall and a second sidewall;
an element isolation pattern disposed in the substrate and surrounding the active area; and
a transfer gate electrode including:
a first portion extending from the first face of the substrate and extending through the element isolation pattern, wherein the first portion includes a first sub-portion extending along the first sidewall and a second sub-portion extending along the second sidewall; and
a second portion on the active area,
wherein the transfer gate electrode overlaps the photoelectric conversion area along the first direction and is non-overlapping with the photoelectric conversion area in a direction parallel to at least one of the first face or the second face of the substrate.

13. The image sensor of claim 12, wherein the active area includes a third sidewall connecting the first sidewall and the second sidewall to one another.

14. The image sensor of claim 13, wherein the first sidewall and the second sidewall are opposite one another.

15. The image sensor of claim 13, wherein the first portion of the transfer gate electrode includes a third sub-portion extending along the third sidewall and extending through the element isolation pattern.

16. The image sensor of claim 15, wherein the first sub-portion, the second sub-portion and the third sub-portion are connected to one another.

17. The image sensor of claim 12, wherein the first sidewall and the second sidewall are in contact with one another.

18.-19. (canceled)

20. An image sensor comprising:
a substrate including a first face and a second face opposite one another along a first direction;
a pixel isolation pattern extending from the second face of the substrate into the substrate, wherein the pixel isolation pattern defines a plurality of pixels;
at least one color filter disposed on the second face of the substrate; and
at least one micro lens disposed on the color filter,
wherein each of the plurality of pixels includes:
a photoelectric conversion area disposed in the substrate;
an active area disposed in the substrate and on the photoelectric conversion area;
an element isolation pattern extending from the first face of the substrate into the substrate and contacting the pixel isolation pattern, wherein the element isolation pattern defines the active area; and
a transfer gate electrode including:
a first portion extending from the first face of the substrate and extending through the element isolation pattern; and
a second portion disposed on the active area,
wherein the first portion extends through a bottom face of the element isolation pattern, and
wherein a vertical level of a bottom face of the first portion is lower than a vertical level of the bottom face of the element isolation pattern.

21. The image sensor of claim 20, wherein the plurality of pixels includes a first pixel, a second pixel, and a third pixel, the second pixel and the third pixel adjacent to one another,
wherein the at least one micro lens includes a first micro lens disposed on the first pixel, and a second micro lens disposed on the second and third pixels.

22. The image sensor of claim 20, wherein the plurality of pixels includes first to fourth pixels arranged in two rows and two columns, and
wherein the image sensor comprises:
a shared active area disposed in the substrate and between the first to fourth pixels, the shared active area defined by the element isolation pattern; and
a floating diffusion area disposed in the shared active area.

23. The image sensor of claim 20, wherein the image sensor comprises a floating diffusion area disposed in the active area.

24. The image sensor of claim 20, wherein the plurality of pixels includes first to fourth pixel groups, each pixel group including at least one of the plurality of pixels,
wherein the second pixel group is adjacent to the first pixel group in a second direction,
wherein the third pixel group is adjacent to the first pixel group in a third direction,
wherein the fourth pixel group is adjacent to the second pixel group in the third direction,
wherein the at least one color filter comprises
a first color filter disposed on the first pixel group
a second color filter disposed on the second pixel group and the third pixel group, and
a third color filter disposed on the fourth pixel group,
wherein the first color filter, the second color filter, and the third color filter have different color characteristics from one another.
